(19) United States
(12) Patent Application Publication
(10) Pub. No.: US 2016/0226487 A1
(43) Pub. Date: Aug. 4, 2016

(54) SEMICONDUCTOR DEVICE

(71) Applicant: ROHM CO., LTD., Kyoto (JP)

(72) Inventor: Kiyotaka Umemoto, Kyoto (JP)

(21) Appl. No.: 15/010,380

(22) Filed: Jan. 29, 2016

(30) Foreign Application Priority Data
Feb. 2, 2015 (JP) 2015018454

(51) Int. Cl. H03K 17/687; H03K 5/08

(52) U.S. Cl. CPC H03K 17/6871; H03K 5/08

(57) ABSTRACT

A semiconductor device includes: a first external terminal which receives an input voltage; a second external terminal which outputs a switch voltage; a third external terminal connected to a first ground; a fourth external terminal connected to a second ground; a first internal switch element formed on a semiconductor substrate to be connected between the first and second external terminals; a second internal switch element formed on the semiconductor substrate to be connected between the second external terminal and the third external terminal; and a control circuit connected to the fourth external terminal to drive at least one of the first internal switch element and the second internal switch element. The semiconductor substrate is electrically connected with the third external terminal rather than the fourth external terminal, and parasitic elements accompanied between the semiconductor substrate and each of the first internal switch element and the second internal switch element.

### CROSS-REFERENCE TO RELATED APPLICATION

This application is based upon and claims the benefit of priority from Japanese Patent Application No. 2015-018454, filed on Feb. 2, 2015, the entire contents of which are incorporated herein by reference.

### TECHNICAL FIELD

The present disclosure relates to a semiconductor device.

### BACKGROUND

There have conventionally been many cases where an RC filter and a highly-capacitive input capacitor (bypass capacitor) are externally attached, as a noise suppressing means, to a semiconductor device (such as a switching power supply IC) which produces a switching noise when an internal switch element is driven.

However, since the conventional semiconductor device uses the external part to suppress the switching noise, there is a problem of an increase in the number of parts and costs.

In addition, when an RC filter is built in a semiconductor device in the related art, there has been proposed a technique for effectively using an element formation area by utilizing parasitic capacitance of a diffusion resistor instead of forming a resistor and a capacitor separately. However, this proposed technique has no disclosure and even suggestion on the effect that a parasitic element accompanied with an internal switch element is utilized as a noise filter.

### SUMMARY

The present disclosure provides some embodiments of a semiconductor device which is capable of suppressing a switching noise by using a parasitic element associated with an internal switch element, a switching power supply including the semiconductor device, and an electronic apparatus including the switching power supply.

According to one embodiment of the present disclosure, there is provided a semiconductor device including: a first external terminal which receives an input voltage; a second external terminal which outputs a switch voltage; a third external terminal connected to a first ground; a fourth external terminal connected to a second ground; a first internal switch element formed on a semiconductor substrate to be connected between the first external terminal and the second external terminal; a second internal switch element formed on the semiconductor substrate to be connected between the second external terminal and the third external terminal; and a control circuit connected to the fourth external terminal to drive at least one of the first internal switch element and the second internal switch element, wherein the semiconductor substrate is electrically connected with the third external terminal rather than the fourth external terminal and parasitic elements accompanied between the semiconductor substrate and each of the first internal switch element and the second internal switch element.

In some embodiments, a substrate contact region for establishing electrical connection with the third external terminal may be formed on the semiconductor substrate in a position which is near the first internal switch element and far from the second internal switch element.

In some embodiments, the first internal switch element may be a first NMOSFET (N-channel type Metal Oxide Semiconductor Field Effect Transistor) having a drain connected to the first external terminal, and a source and a back gate, both of which are connected to the second external terminal.

In some embodiments, a first parasitic capacitor accompanied between the drain of the first NMOSFET and the substrate contact region may act as an input capacitor connected between the first external terminal and the third external terminal.

In some embodiments, the second internal switch element may be a second NMOSFET having a drain connected to the second external terminal, and a source and a back gate, both of which are connected to the third external terminal.

In some embodiments, the second internal switch element may be a diode having a cathode connected to the second external terminal and an anode connected to the third external terminal.

In some embodiments, a second parasitic capacitor and a parasitic resistor accompanied between the drain of the second NMOSFET or the cathode of the diode and the substrate contact region may act as an RC filter connected between the second external terminal and the third external terminal.

In some embodiments, the control circuit may be formed in a well which is electrically separated from the semiconductor substrate and electrically connected with the fourth external terminal.

According to another embodiment of the present disclosure, there is provided a switching power supply including: the above-described semiconductor device; and a rectifying/smoothing part which rectifies and smooths the switch voltage output from the semiconductor device to generate an output voltage.

According to another embodiment of the present disclosure, there is provided an electronic apparatus including: the above-described switching power supply.

### BRIEF DESCRIPTION OF THE DRAWINGS

FIG. 1 is a circuit diagram showing a first embodiment of a power supply 1.

FIG. 2 is a longitudinal sectional view showing a structure example of a semiconductor device 10 according to the first embodiment.

FIG. 3 is a timing chart showing one example of a switching operation according to the first embodiment.

FIG. 4 is a circuit diagram showing a second embodiment of the power supply 1.

FIG. 5 is a longitudinal sectional view showing a structure example of a semiconductor device 10 according to the second embodiment.

FIG. 6 is a timing chart showing one example of a switching operation according to the second embodiment.

FIG. 7 is a circuit diagram showing a third embodiment of the power supply 1.

FIG. 8 is a longitudinal sectional view showing a structure example of a semiconductor device 10 according to the third embodiment.

FIG. 9 is a view showing the external appearance of a smartphone A.

FIG. 10 is a view showing the external appearance of a tablet terminal B.

### DETAILED DESCRIPTION

### First Embodiment

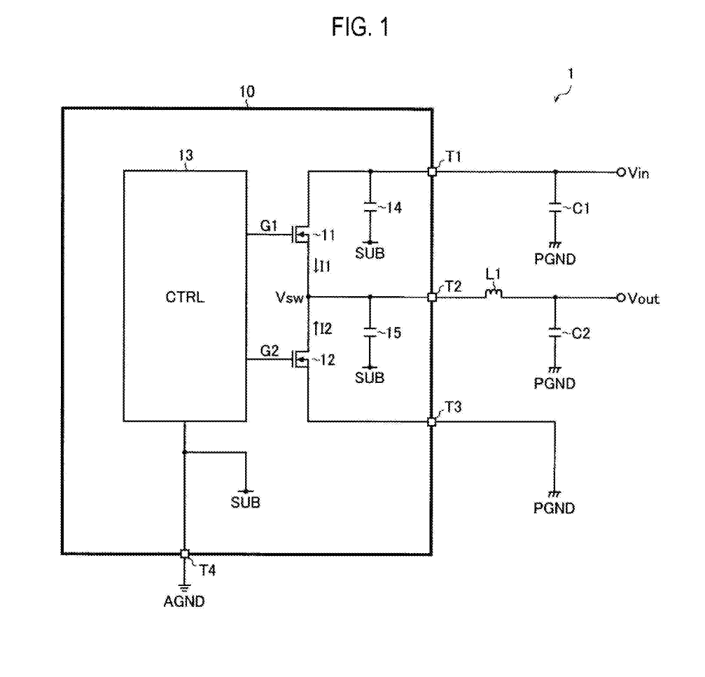

FIG. 1 is a circuit diagram showing a first embodiment of a power supply 1. In this embodiment, the power supply 1 is a step-down switching power supply for stepping down an input voltage Vin to generate a desired output voltage Vout, and includes a semiconductor device 10 and various kinds of discrete components (an input capacitor (bypass capacitor) C1, an output capacitor C2 and an output inductor L1) externally attached thereto.

The semiconductor device 10 is a control entity of the power supply 1 (a so-called switching power supply IC) and has external terminals T1 to T4 which are means for establishing electrical connection with the outside of the device 10. The external terminal T1 is an input terminal for receiving the input voltage Vin. The external terminal T2 is a switch terminal for outputting a switch voltage Vsw. The external terminal T3 is a first ground terminal connecting to a first ground PGND. The fourth external terminal T4 is a second ground terminal connecting to a second ground AGND. Of course, the semiconductor device 10 may be appropriately provided with external terminals (such as a feedback terminal for receiving the output voltage Vout and a feedback voltage Vfb (corresponding to a divided voltage of the output voltage Vout), and the like) other than the external terminals T1 to T4.

First, the connection relationship between the external terminals T1 to T4 and the discrete components C1, C2 and L1 will be described as follows. The external terminal T1 is connected to an input terminal of the input voltage Vin and a first end of the input capacitor C1. A second end of the input capacitor C1 is connected to the first ground PGND. The input capacitor C1 acts as a power supply filter for lowering AC impedance between the input terminal of the input voltage Vin and the first ground PGND and suppressing a switching noise superimposed on the switch voltage Vsw. The external terminal T2 is connected to a first end of the output inductor L1. A second end of the output inductor L1 and a first end of the output capacitor C2 are both connected to an output terminal of the output voltage Vout. A second end of the output capacitor C2 is connected to the first ground PGND. A combination of the output inductor L1 and the output capacitor C2 acts as a rectifying/smoothing part for rectifying and smoothing the switch voltage Vsw output from the semiconductor device 10 to thereby generate the output voltage Vout. The external terminal T3 is connected to the first ground PGND. The external terminal T4 is connected to the second ground AGND.

Next, the internal configuration of the semiconductor device 10 will be described. An output transistor 11, a synchronous rectification transistor 12 and a control circuit 13 are integrated in the semiconductor device 10.

The output transistor 11 is a first NMOSFET (first internal switch element) which is formed on a semiconductor substrate SUB and is connected between the external terminal T1 and the external terminal T2. In more detail for the connection relationship thereof, the drain of the output transistor 11 is connected to the external terminal T1. The source and back gate of the output transistor 11 are both connected to the external terminal T2. The gate of the output transistor 11 is connected to an output terminal of a first gate signal G1. The output transistor 11 is turned on in a high-level period of the first gate signal G1 and is turned off in a low-level period of the first gate signal G1.

The synchronous rectification transistor 12 is a second NMOSFET (second internal switch element) which is formed on the semiconductor substrate SUB and is connected between the external terminal T2 and the external terminal T3. In more detail for the connection relationship thereof, the drain of the synchronous rectification transistor 12 is connected to the external terminal T2. The source and back gate of the synchronous rectification transistor 12 are both connected to the external terminal T3. The gate of the synchronous rectification transistor 12 is connected to an output terminal of a second gate signal G2. The synchronous rectification transistor 12 is turned on in a high-level period of the second gate signal G2 and is turned off in a low-level period of the second gate signal G2.

The control circuit 13 generates the first gate signal G1 and the second gate signal G2 to drive the output transistor 11 and the synchronous rectification transistor 12 complementarily such that the output voltage Vout reaches a desired value. As a result, a switch voltage Vsw of a square wave, which pulses between Vin and PGND, is generated at the external terminal T2. The term “complementarily” used herein includes a case where the simultaneous OFF period (so-called dead time) of the output transistor 11 and the synchronous rectification transistor 12 is provided for the purpose of preventing a through-current, in addition to a case where the ON/OFF state of the output transistor 11 and the synchronous rectification transistor 12 is completely reversed. In addition, the control circuit 13 is connected to the external terminal T4 and operates with the second ground AGND as a reference potential. The control circuit 13 may employ an output feedback scheme such as a PWM (Pulse Width Modulation) scheme or a PFM (Pulse Frequency Modulation) which is well-known in the art and, therefore, detailed explanation of which is omitted.

In this way, a switching output stage of a synchronous rectification type is formed in the semiconductor device 10 of the first embodiment by using the output transistor 11 and the synchronous rectification transistor 12 connected in series between the external terminal T1 and the external terminal T3.

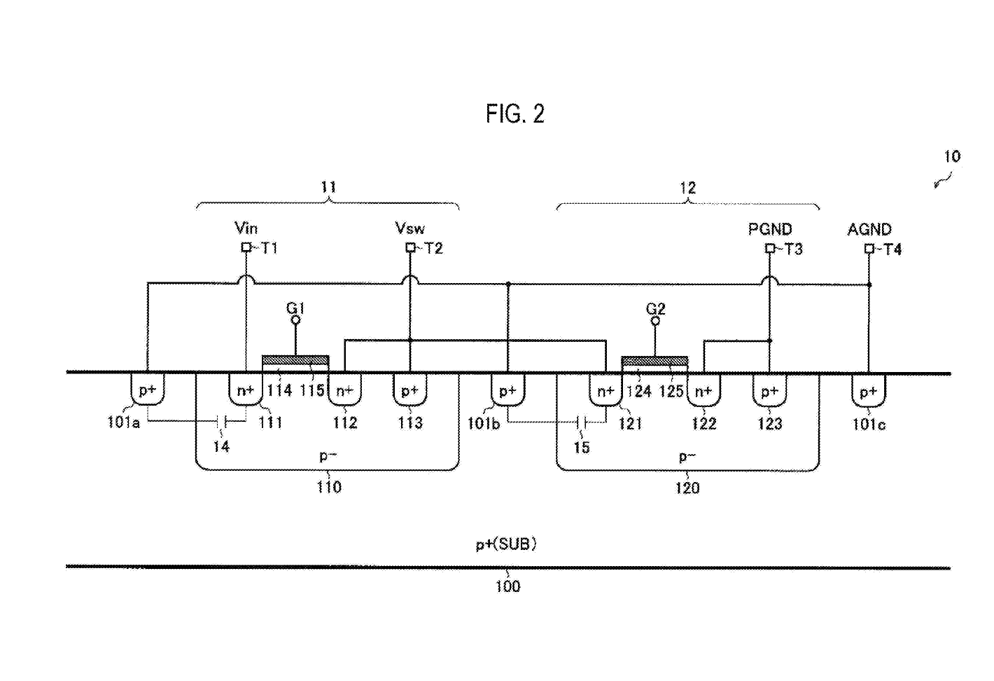

In addition, a first parasitic capacitor 14 and a second parasitic capacitor 15 are respectively interposed between the drain of the output transistor 11 and the semiconductor substrate SUB and between the drain of the synchronous rectification transistor 12 and the semiconductor substrate SUB, respectively. However, in the semiconductor device 10 according to the first embodiment, the semiconductor substrate SUB is electrically connected with the external terminal T4 (the second ground AGND). Therefore, the first parasitic capacitor 14 and the second parasitic capacitor 15 do not act as a noise filter of the switching output stage. A structure of the semiconductor device 10 will be described in detail below with reference to FIG. 2.

FIG. 2 is a longitudinal sectional view showing a structure example of the semiconductor device 10 according to the first embodiment. In the semiconductor device 10 of this structure example, a low-concentration p-type well 110, which is an active area for forming the output transistor 11, is formed in a p-type semiconductor substrate 100 (corresponding to the semiconductor substrate SUB of FIG. 1). High-concentration n-type diffusion areas 111 and 112 and high-concentration p-type diffusion area 113 are formed in the low-concentration p-type well 110.

The high-concentration n-type diffusion area 111 corresponds to the drain region of the output transistor 11 and is connected to the external terminal T1 (i.e., the input terminal of the input voltage Vin). The high-concentration n-type diffusion area 112 corresponds to the source region of the output transistor 11 and is connected to the external terminal T2 (i.e., the output terminal of the switch voltage Vsw). The high-concentration p-type diffusion area 113 corresponds to the back gate contact region of the output transistor 11 and is connected to the external terminal T2, like the high-concentration n-type diffusion area 112.

An oxide layer 114 and a metal layer 115 are formed on a channel region spanning between the high-concentration n-type diffusion areas 111 and 112. The metal layer 115 corresponds to the gate of the output transistor 11 and is connected to an input terminal of the first gate signal G1.

In addition, in the semiconductor device 10 of this structure example, a low-concentration p-type well 120, which is an active area for forming the synchronous rectification transistor 12, is formed in the p-type semiconductor substrate 100. High-concentration n-type diffusion areas 121 and 122 and high-concentration p-type diffusion area 123 are formed in the low-concentration p-type well 120.

The high-concentration n-type diffusion area 121 corresponds to the drain region of the synchronous rectification transistor 12 and is connected to the external terminal T2. The high-concentration n-type diffusion area 122 corresponds to the source region of the synchronous rectification transistor 12 and is connected to the external terminal T3 (i.e., the first ground PGND). The high-concentration p-type diffusion area 123 corresponds to the back gate contact region of the synchronous rectification transistor 12 and is connected to the external terminal T3, like the high-concentration n-type diffusion area 122.

An oxide layer 124 and a metal layer 125 are formed on a channel region spanning between the high-concentration n-type diffusion areas 121 and 122. The metal layer 125 corresponds to the gate of the synchronous rectification transistor 12 and is connected to an input terminal of the second gate signal G2.

Meanwhile, in the semiconductor device 10 of this structure example, a plurality of high-concentration p-type diffusion areas 101a to 101c is formed in a field region of the p-type semiconductor substrate 100. These high-concentration p-type diffusion areas 101a to 101c correspond to substrate contact regions, respectively, and are all connected to the external terminal T4 (i.e., the second ground AGND).

In addition, the first parasitic capacitor 14 is accompanied between the drain region of the output transistor 11 (i.e., the high-concentration n-type diffusion area 111) and the proximate substrate contact region (i.e., the high-concentration p-type diffusion areas 101a). In addition, the second parasitic capacitor 15 is accompanied between the drain region of the synchronous rectification transistor 12 (i.e., the high-concentration n-type diffusion area 121) and the proximate substrate contact region (i.e., the high-concentration p-type diffusion areas 101b).

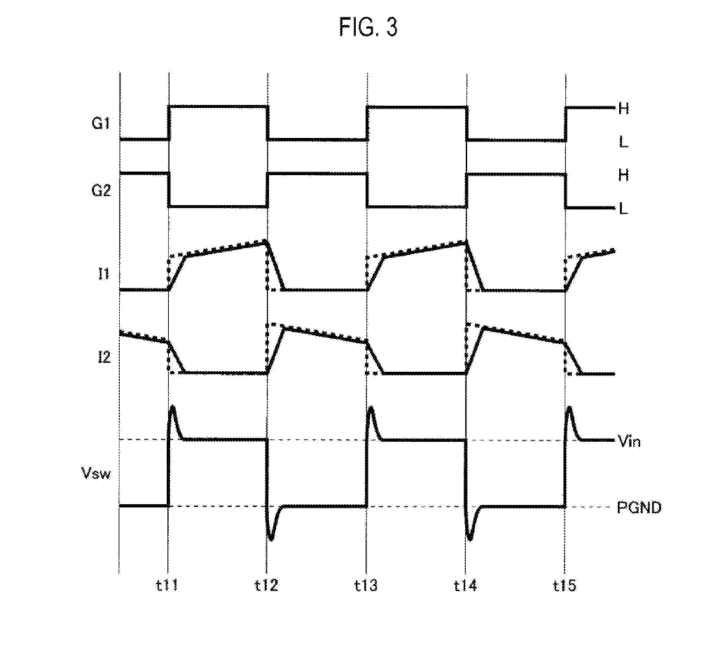

FIG. 3 is a timing chart showing one example of a switching operation according to the first embodiment, depicting the first gate signal G1, the second gate signal G2, a first switch current I1 (i.e., a current flowing from the drain of the output transistor 11 to the source thereof), a second switch current I2 (i.e., a current flowing from the source of the synchronous rectification transistor 12 to the drain thereof), and the switch voltage Vsw, in order from the top.

At time t11 to time t12 and time t13 to time t14, since the first gate signal G1 becomes a high level and the second gate signal G2 becomes a low level, the output transistor 11 is tuned on and the synchronous rectification transistor 12 is turned off. As a result, during the same periods, the first switch current I1 increases and the second switch current I2 decreases and, at the same time, the switch voltage Vsw rises from PGND to Vin.

On the other hand, at time t12 to time t13 and time t14 to time t15, since the first gate signal G1 becomes a low level and the second gate signal G2 becomes a high level, the output transistor 11 is tuned off and the synchronous rectification transistor 12 is turned on. As a result, during the same periods, the first switch current I1 decreases and the second switch current I2 increases and, at the same time, the switch voltage Vsw falls from Vin to PGND.

In addition, at the time of switching between the output transistor 11 and the synchronous rectification transistor 12, it is desirable that the first switch current I1 and the second switch current I2 vary sharply (see broken lines in this figure). However, if the capacitance of the input capacitor C1 is insufficient, since the variation of the first switch current I1 and the second switch current I2 cannot be sufficiently preserved, rising and falling of the first switch current I1 and the second switch current I2 becomes duller than those of the ideal state (see solid lines in this figure). Such dullness of the first switch current I1 and the second switch current I2 becomes one of the causes of producing a switching noise in the switch voltage Vsw.

As one measure against the switching noise, it may be considered to increase the capacitance of the input capacitor C1 or attach an RC filter to the external terminal T2. However, it is hard to say that such a measure is the best policy since it causes increase in the number of components and increase in expense of the set.

### Second Embodiment

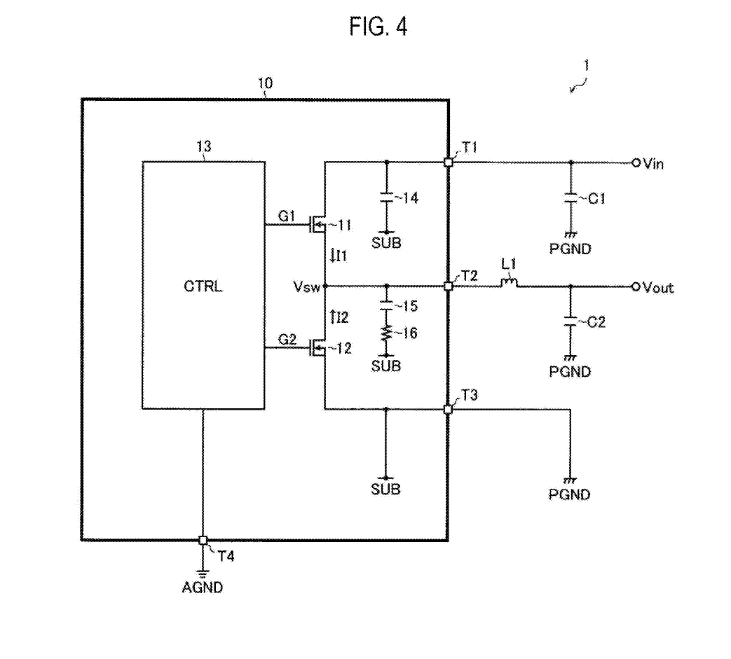

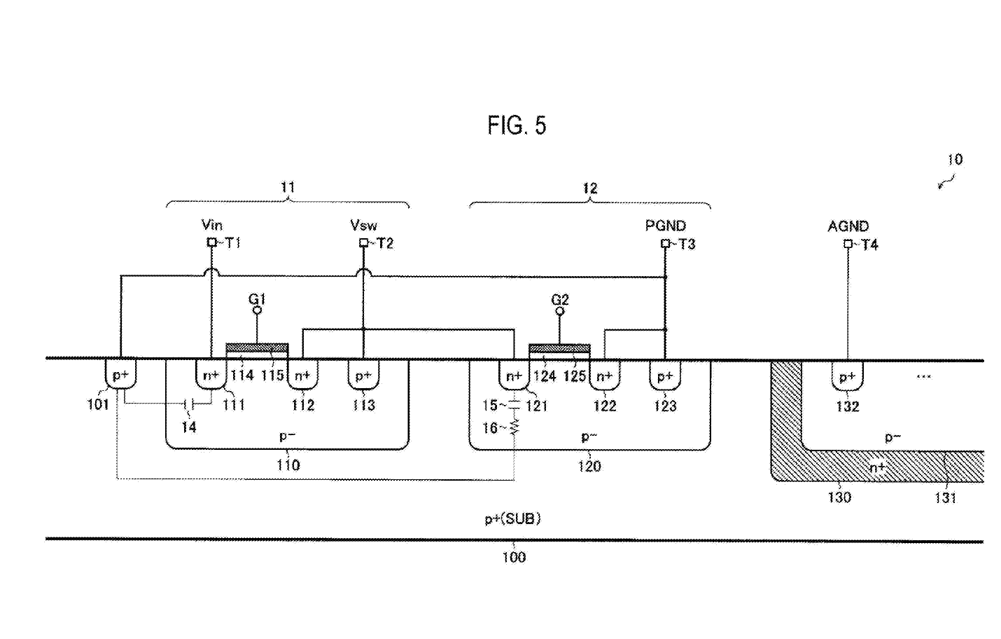

FIG. 4 is a circuit diagram showing a second embodiment of the power supply 1. In this embodiment, the power supply 1 is configured basically similar to that of the first embodiment except that the semiconductor substrate SUB is electrically connected with the external terminal T3 (i.e., the first ground PGND) rather than the external terminal T4 (i.e., the second ground AGND) and the semiconductor device 10 is structured such that parasitic elements (the parasitic capacitors 14 and 15, and a parasitic resistor 16), which are accompanied between the drain of the output transistor 11 and the semiconductor substrate SUB and between the drain of the synchronous rectification transistor 12 and the semiconductor substrate SUB, respectively, act as a noise filter. The structure of the semiconductor device 10 will be described in detail below with reference to FIG. 5.

FIG. 5 is a longitudinal sectional view showing a structure example of the semiconductor device 10 according to the second embodiment. The semiconductor device 10 of this embodiment is formed basically similar to the structure shown in FIG. 2 except that the high-concentration p-type diffusion area 101 corresponding to the substrate contact region is connected to the external terminal T3 (i.e., the first ground PGND) rather than the external terminal T4.

With such change in the structure of the semiconductor device 10, the first parasitic capacitor 14, which is accompanied between the drain region of the output transistor 11 (i.e., the high-concentration n-type diffusion area 111) and the proximate substrate contact region (i.e., the high-concentration p-type diffusion area 101), acts as an input capacitor (bypass filter) connected between the external terminal T1 and the external terminal T3.

Accordingly, in the semiconductor device 10 of this embodiment, since the rising/falling of the first switch current I1 and the second switch current I2 can be made sharp without causing unnecessary increase in the capacitance of the input capacitor C1, it is possible to suppress occurrence of a switching noise superimposed on the switch voltage Vsw.

In addition, the semiconductor device 10 of this embodiment is further characterized in that the substrate contact region (i.e., the high-concentration p-type diffusion area 101) is formed in a position (for example, proximate to high-concentration n-type diffusion area 111) which is near the output transistor 11 and far from the synchronous rectification transistor 12 instead of forming the plurality of substrate contact regions 101a to 101c in the field region of the semiconductor substrate 100, unlike that shown in FIG. 2.

With such change in structure of the semiconductor device 10, the parasitic resistor 16 as well as the second parasitic capacitor 15 is accompanied between the drain region of the synchronous rectification transistor 12 (i.e., the high-concentration n-type diffusion area 121) and the substrate contact region (i.e., the high-concentration p-type diffusion area 101). These second parasitic capacitor 15 and parasitic resistor 16 act as an RC filter connected in series between the external terminal T2 and the external terminal T3.

Accordingly, in the semiconductor device 10 of this embodiment, since the switch voltage Vsw can be made dull without attaching the RC filter to the external terminal T2, it is possible to effectively suppress a switching noise even if the switching noise is superimposed on the switch voltage Vsw. In addition, the resistance of the parasitic resistor 16 increases as a distance between the drain region of the synchronous rectification transistor 12 and the substrate contact region increases.

In this way, in the semiconductor device 10 of this embodiment, since the switching noise can be suppressed by using the parasitic elements 14 to 16 accompanied with the output transistor 11 and the synchronous rectification transistor 12, it is possible to reduce the number of components and reduce the entire expense of the set. In particular, as long as the switching noise can be suppressed by using only the parasitic elements 14 to 16, the input capacitor C1 and the RC filter may not be attached to the semiconductor device 10 at all.

In addition, if the switching noise can be sufficiently suppressed by only the input capacitor C1 and the first parasitic capacitor 14, there is no need for the RC filter composed of the second parasitic capacitor 15 and the parasitic resistor 16. Since this eliminates a need of increasing a distance between the drain region of the synchronous rectification transistor 12 (i.e., the high-concentration n-type diffusion area 121) and the substrate contact region (i.e., the high-concentration p-type diffusion area 101) (that is, a need of accompanying the parasitic resistor 16), both transistors may be disposed adjacent to each other.

In addition, the semiconductor device 10 of this embodiment is further characterized in that a circuit element (such as the control circuit 13) operating with the AGND as a reference is formed in a well which is electrically separated from the semiconductor substrate 100 and electrically connected with the external terminal T4 (i.e., the second ground AGND).

In more detail, a high-concentration n-type well 130 is formed in the p-type semiconductor substrate 100. A low-concentration p-type well 131 is formed in the high-concentration n-type well 130. A high-concentration p-type diffusion area 132 as a well contact region which is electrically connected with the external terminal T4 and various types of circuit elements (not shown) including the control circuit 13 are formed in the low-concentration p-type well 131. In addition, the high-concentration n-type well 130 acts as an element isolation region for making electrical isolation between the p-type semiconductor substrate 100 and the low-concentration p-type well 131.

By employing such a device structure, since the circuit element operating with the AGND as a reference can be electrically separated from the first ground PGND susceptible to the switching noise, the operation of the circuit element can be stabilized.

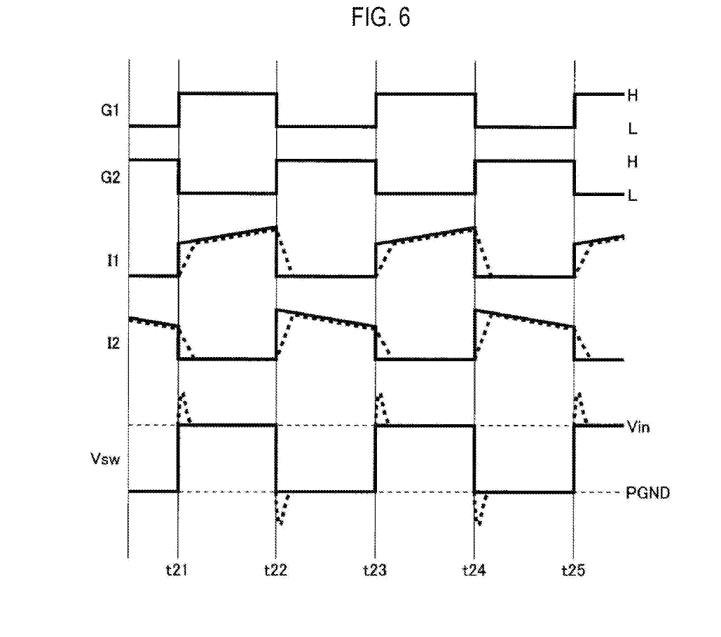

FIG. 6 is a timing chart showing one example of a switching operation according to the second embodiment, depicting the first gate signal G1, the second gate signal G2, the first switch current I1, the second switch current I2, and the switch voltage Vsw, in order from the top, like FIG. 3.

As in FIG. 3, at time t21 to time t22 and time t23 to tine t24, since the first gate signal G1 becomes a high level and the second gate signal G2 becomes a low level, the output transistor 11 is turned on and the synchronous rectification transistor 12 is turned off. As a result, during the same periods, the first switch current I1 increases and the second switch current I2 decreases and, at the same time, the switch voltage Vsw rises from PGND to Vin.

On the other hand, at time t22 to t23 and time t24 to t25, since the first gate signal G1 becomes a low level and the second gate signal G2 becomes a high level, the output transistor 11 is tuned off and the synchronous rectification transistor 12 is turned on. As a result, during the same periods, the first switch current I1 decreases and the second switch current I2 increases and, at the same time, the switch voltage Vsw falls from Vin to PGND.

In addition, in the semiconductor device 10 of this embodiment, as described earlier, since the first parasitic capacitor 14 acts as an input capacitor, the rising/falling of the first switch current I1 and the second switch current I2 can be made sharp, thereby suppressing occurrence of a switching noise.

In addition, in the semiconductor device 10 of this embodiment, as described earlier, since the parasitic capacitor 15 and the parasitic resistor 16 act as an RC filter, it is possible to effectively suppress a switching noise superimposed on the switch voltage Vsw.

### Third Embodiment

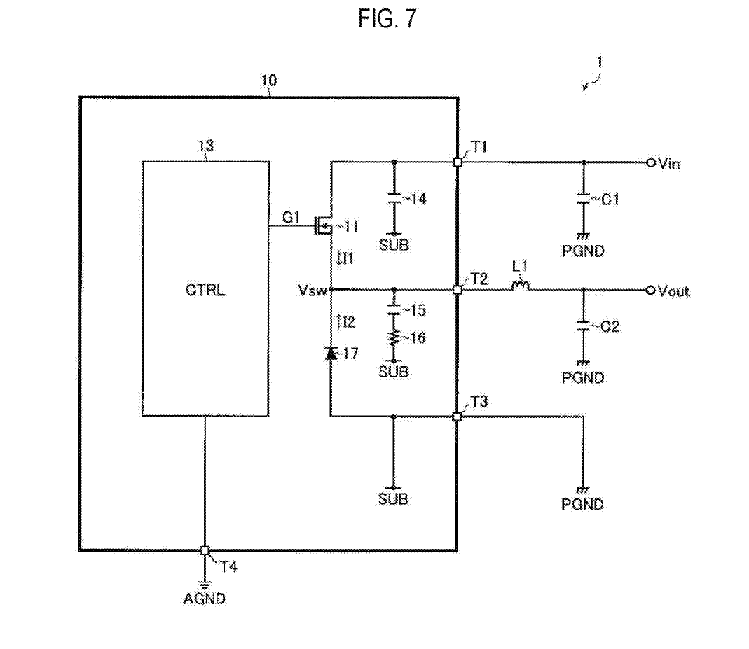

FIG. 7 is a circuit diagram showing a third embodiment of the power supply 1. In this embodiment, the power supply 1 is configured basically similar to that of the second embodiment except that a rectification diode 17 instead of the synchronous rectification transistor 12 is used as the second internal switch element forming the switching output stage. The rectification diode 17 has a cathode connected to the external terminal T2 and an anode connected to the external terminal T3.

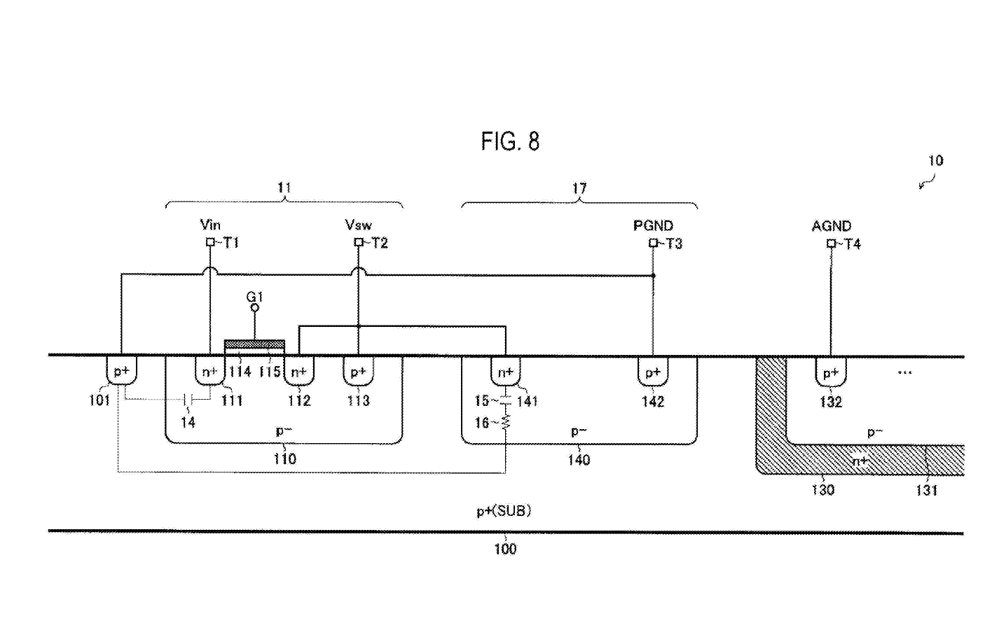

FIG. 8 is a longitudinal sectional view showing a structure example of the semiconductor device 10 according to the third embodiment. The semiconductor device 10 of this structure example basically has the same structure as that shown in FIG. 5 except that the rectification diode 17 is formed instead of the synchronous rectification transistor 12.

In more detail, in the semiconductor device 10 of this structure example, a low-concentration p-type well 140 as an active area for forming the rectification diode 17 is formed in the p-type semiconductor substrate 100. A high-concentration n-type diffusion area 141 and a high-concentration p-type diffusion area 142 are formed in the low-concentration p-type well 140.

The high-concentration n-type diffusion area 141 corresponds to a cathode region of the rectification diode 17 and is connected to the external terminal T2. The high-concentration p-type diffusion area 142 corresponds to an anode region of the rectification diode 17 and is connected to the external terminal T3 (i.e., the first ground PGND).

In addition, the parasitic resistor 16 as well as the second parasitic capacitor 15 is accompanied between the cathode region of the rectification diode 17 (i.e., the high-concentration n-type diffusion area 141) and the substrate contact region ((i.e., the high-concentration p-type diffusion area 101). These second parasitic capacitor 15 and parasitic resistor 16 act as an RC filter connected in series between the external terminal T2 and the external terminal T3.

In this way, the device structure for actively utilizing the parasitic elements 14 to 16 accompanied with the switching output stage can be applied to not only the switching power supply IC of the synchronous rectification type but also a switching power supply IC of a diode rectification type.

### <Electronic Apparatus>

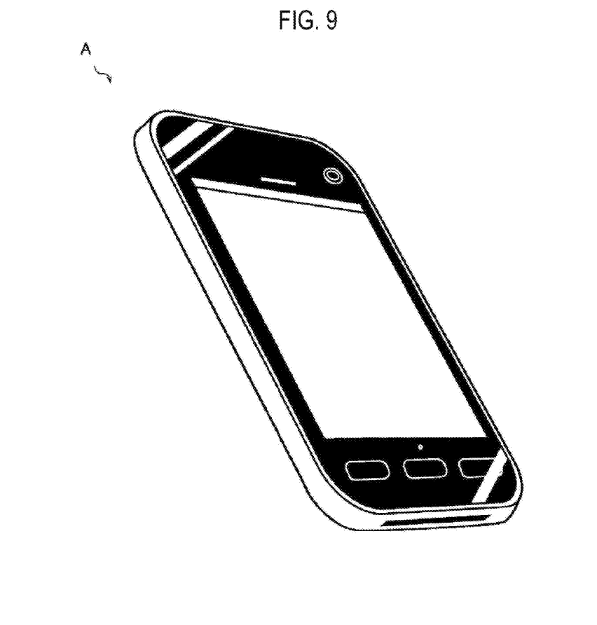

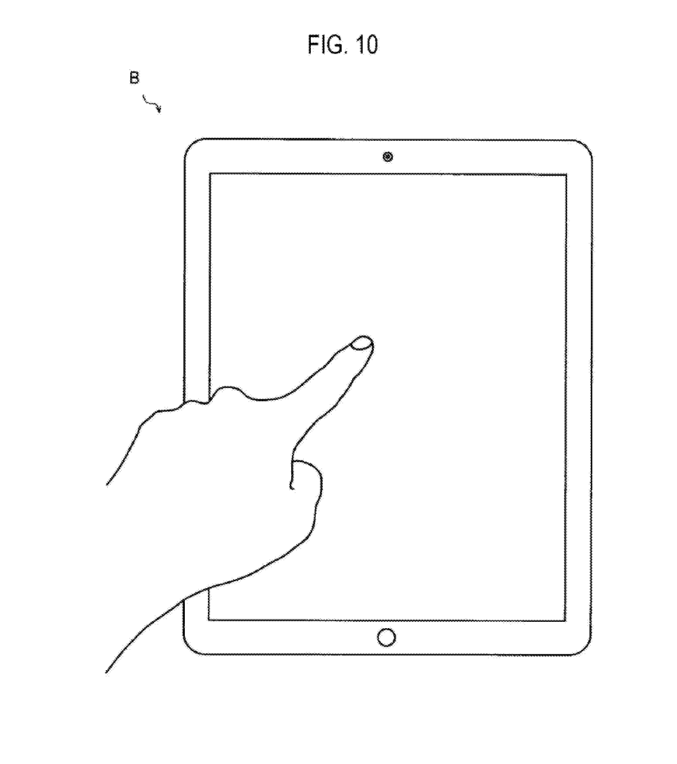

FIGS. 9 and 10 show a smartphone A and a tablet terminal B, respectively. The smartphone A and the tablet terminal B are examples of an electronic apparatus equipped with the above-described power supply 1. However, the target object to be equipped with the power supply 1 is not limited thereto. For example, the power supply 1 can be applied in a wide range including the general electronic apparatuses (such as notebook computers and portable game machines) requiring their compactness, lightness and thinness.

### <Other Modifications>

The above-described embodiments and other various technical features disclosed in the specification can be modified in different ways without departing from the spirit of the disclosure. For example, although all of the above-described first to third embodiments have been illustrated with the switching power IC, the present disclosure is not limited thereto but may be widely applied to semiconductor devices (such as motor driver ICs) provided for other uses.

### INDUSTRIAL APPLICABILITY

The present disclosure can be used for, for example, a switching power supply IC.

According to the present disclosure in some embodiments, it is possible to provide a semiconductor device which is capable of preventing a switching noise by using a parasitic element associated with an internal switch element, a switching power supply including the semiconductor device, and an electronic apparatus including the switching power supply.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first external terminal which receives an input voltage;
a second external terminal which outputs a switch voltage;
a third external terminal connected to a first ground;
a fourth external terminal connected to a second ground;
a first internal switch element formed on a semiconductor substrate to be connected between the first external terminal and the second external terminal;
a second internal switch element formed on the semiconductor substrate to be connected between the second external terminal and the third external terminal; and
a control circuit connected to the fourth external terminal to drive at least one of the first internal switch element and the second internal switch element,
wherein the semiconductor substrate is electrically connected with the third external terminal rather than the fourth external terminal, and parasitic elements accompanied between the semiconductor substrate and each of the first internal switch element and the semiconductor substrate.

2. The semiconductor device of claim 1, wherein a substrate contact region for establishing electrical connection with the third external terminal is formed on the semiconductor substrate in a position which is near the first internal switch element and far from the second internal switch element.

3. The semiconductor device of claim 2, wherein the first internal switch element is a first NMOSFET (N-channel type Metal Oxide Semiconductor Field Effect Transistor) having a drain connected to the first external terminal, and a source and a back gate, both of which are connected to the second external terminal.

4. The semiconductor device of claim 3, wherein a first parasitic capacitor accompanied between the drain of the first NMOSFET and the substrate contact region acts as an input capacitor connected between the first external terminal and the third external terminal.

5. The semiconductor device of claim 2, wherein the second internal switch element is a second NMOSFET having a drain connected to the second external terminal, and a source and a back gate, both of which are connected to the third external terminal.

6. The semiconductor device of claim 2, wherein the second internal switch element is a diode having a cathode connected to the second external terminal and an anode connected to the third external terminal.

7. The semiconductor device of claim 5, wherein a second parasitic capacitor and a parasitic resistor accompanied between the drain of the second NMOSFET or the cathode of the diode and the substrate contact region act as an RC filter connected between the second external terminal and the third external terminal.

8. The semiconductor device of claim 1, wherein the control circuit is formed in a well which is electrically separated from the semiconductor substrate and electrically connected with the fourth external terminal.

9. A switching power supply comprising:
a semiconductor device of claim 1; and
a rectifying/smoothing part which rectifies and smooths the switch voltage output from the semiconductor device to generate an output voltage.

10. An electronic apparatus comprising: a switching power supply of claim 9.
